(19) United States
(12) Patent Application Publication
(10) Pub. No.: US 2018/0069127 A1
(43) Pub. Date: Mar. 8, 2018

(54) THIN FILM TRANSISTOR OF DISPLAY PANEL

(71) Applicant: AU Optronics Corporation, HSIN-CHU (TW)

(72) Inventor: Yu-Xin YANG, HSIN-CHU (TW)

(21) Appl. No.: 15/604,843

(22) Filed: May 25, 2017

(30) Foreign Application Priority Data
Sep. 7, 2016 (TW) 105128841

(51) Int. Cl. H01L 29/786; H01L 51/00; H01L 29/66

(52) U.S. Cl. CPC H01L 29/78633; H01L 29/78603; H01L 51/0097; H01L 51/0541; H01L 29/66757; H01L 29/78666; H01L 29/7869; H01L 29/66969

(57) ABSTRACT

A thin film transistor of a display panel includes a patterned light absorption layer, a patterned semiconductor layer, a patterned gate insulating layer, a gate, a source and a drain. The patterned light absorption layer is disposed on a transparent substrate. The patterned semiconductor layer is disposed on the patterned light absorption layer. The patterned gate insulating layer is disposed on the patterned semiconductor layer. The gate is disposed on the patterned gate insulating layer. The source and the drain are disposed above the patterned semiconductor layer and electrically connected to the patterned semiconductor layer respectively.

### BACKGROUND

### Technical Field

The present invention relates to a thin film transistor of a display panel, and in particular, to a thin film transistor of a display panel capable of reducing influence of illumination on a threshold voltage of the thin film transistor.

### Related Art

An active matrix display panel includes a plurality of pixel structures that are arranged as a matrix, and each pixel structure mainly includes components such as a thin film transistor, a display component, and a storage capacitor. In the present technology, a material of a semiconductor layer in a thin film transistor is usually a material that is not resistant to illumination, but the thin film transistor in a display panel, no matter during a process, packaging, or operation, is likely to be directly illuminated by a light ray having a short-wavelength (for example, white light, blue light, ultraviolet light, or the like), so that a property of the semiconductor layer is influenced to have a change and produce an unfavorable effect of threshold voltage deviation, resulting in an unfavorable shift effect of the thin film transistor, thereby further influencing display quality of the display panel.

In an ordinary display panel, gate metal of a bottom gate thin film transistor or a dual gate thin film transistor is used to shield a light ray from the bottom, but thin film transistors of the two types all have relatively large parasitic capacitance and a disadvantage of difficulty in miniaturization, and processing of the dual gate thin film transistor is complex, which increases manufacturing costs, so that the bottom gate thin film transistor and dual gate thin film transistor are disadvantageous in terms of use in a display panel.

### SUMMARY

One of objectives of the present invention is to provide a thin film transistor, where a light absorption layer is disposed inside the thin film transistor to reduce influence of a light ray on a semiconductor layer, so as to reduce a threshold voltage offset.

An embodiment of the present invention provides a thin film transistor of a display panel, including: a patterned light absorption layer, a patterned semiconductor layer, a patterned gate insulating layer, a gate, a source, and a drain, where the patterned light absorption layer is disposed on a transparent substrate, the patterned semiconductor layer is disposed on the patterned light absorption layer, the patterned gate insulating layer is disposed on the patterned semiconductor layer, the gate is disposed on the patterned gate insulating layer, the source is disposed on the patterned semiconductor layer and electrically connected to the patterned semiconductor layer, and the drain is disposed on the patterned semiconductor layer and electrically connected to the patterned semiconductor layer.

Another embodiment of the present invention provides a method for manufacturing a thin film transistor of a display panel, including the following steps. First, a transparent substrate is provided, and a light absorption layer and a semiconductor layer are formed in sequence on the transparent substrate. Subsequently, a part of the semiconductor layer and a part of the light absorption layer are removed to form a patterned light absorption layer and a patterned semiconductor layer, where a pattern range of the patterned light absorption layer is greater than or equal to a pattern range of the patterned semiconductor layer. Then, a patterned gate insulating layer and a gate are formed on the patterned semiconductor layer, and the patterned gate insulating layer and the gate are stacked in sequence on the patterned semiconductor layer. Finally, a source and a drain are formed on the patterned semiconductor layer, where the source and the drain are electrically connected to the patterned semiconductor layer separately.

Because the thin film transistor of a display panel of the present invention includes a patterned light absorption layer disposed between a transparent substrate and a patterned semiconductor layer, and the patterned light absorption layer can absorb a short-wavelength light ray from a transparent substrate side, an amount of illumination of the short-wavelength light ray from the transparent substrate side onto the patterned semiconductor layer can be reduced, so as to effectively reduce a threshold voltage offset, thereby maintaining a switch effect of the thin film transistor.

### BRIEF DESCRIPTION OF THE DRAWINGS

FIG. 1 to FIG. 5 show schematic diagrams of a method for manufacturing a thin film transistor of a display panel of a first embodiment of the present invention;

FIG. 6 shows an experimental result of a negative bias illumination stress (NBIS) test on a thin film transistor of a display panel of a comparison embodiment of the present invention;

FIG. 7 shows an experimental result of a positive bias illumination stress (PBIS) test on a thin film transistor of a display panel of a comparison embodiment of the present invention;

FIG. 8 shows an experimental result of an NBIS test on the thin film transistor of a display panel of the first embodiment of the present invention;

FIG. 9 shows an experimental result of a PBIS test on the thin film transistor of a display panel of the first embodiment of the present invention;

FIG. 10 to FIG. 14 show schematic diagrams of a method for manufacturing a thin film transistor of a display panel of a second embodiment of the present invention;

FIG. 15 shows a schematic sectional diagram of a thin film transistor of a display panel of a third embodiment of the present invention; and

FIG. 16 shows a schematic sectional diagram of a thin film transistor of a display panel of a fourth embodiment of the present invention.

### DETAILED DESCRIPTION

In order to enable persons of ordinary skill in the art of the present invention to further understand the present invention, preferred embodiments of the present invention are specifically provided in the following text and the constitution content and to-be-produced effects of the present invention are described in detail with reference to the accompanying drawings.

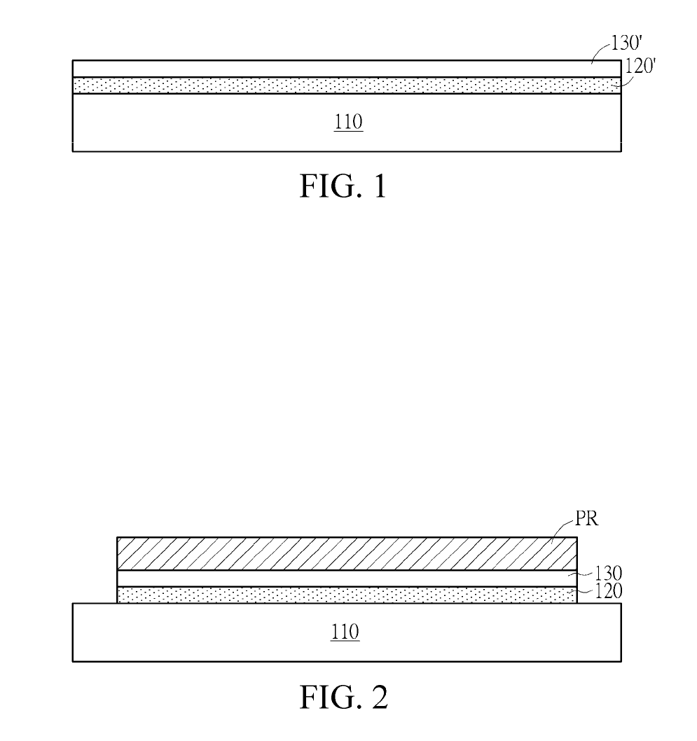

Referring to FIG. 1 to FIG. 5, FIG. 1 to FIG. 5 show schematic diagrams of a method for manufacturing a thin film transistor of a display panel of a first embodiment of the present invention, and FIG. 5 shows a schematic sectional diagram of the thin film transistor of a display panel of the first embodiment of the present invention at the same time. According to a method for manufacturing a thin film transistor 100 of a display panel of the first embodiment of the present invention, first, as shown in FIG. 1, the transparent substrate 110 is provided, and a light absorption layer 120′ and a semiconductor layer 130′ are formed in sequence on the transparent substrate 110, where the light absorption layer 120′ is located between the transparent substrate 110 and the semiconductor layer 130′. In this embodiment, the transparent substrate 110 may be a glass substrate, a plastic substrate, a quartz substrate, a sapphire substrate, or another suitable hard transparent substrate, or a transparent substrate, a material of the light absorption layer 120′, for example, includes an amorphous silicon material or another suitable material, for example, various color resists such as a black color resist, a red color resist, and a green color resist, and a material of the semiconductor layer 130′ may selectively be a metal oxide semiconductor material including indium, zinc, tin, gallium, or a combination of the foregoing elements, for example, indium gallium zinc oxide (IGZO), indium tin zinc oxide (ITZO), zinc oxide (ZnO), or another suitable metal oxide material and may also selectively be a P-type or N-type organic semiconductor material or an amorphous silicon semiconductor or the like, but the present invention is not limited thereto. In addition, in this embodiment, a thickness range light absorption layer 120′ may be from about 100 Å to about 3000 Å, and preferably, the thickness range is from about 300 Å to about 1000 Å, it is worth noting that when the thickness range of the light absorption layer 120′ is greater than 300 Å, because the thickness is enough, a short-wavelength (for example, ultraviolet light, blue light, or another wavelength) absorption effect can be apparently improved, and moreover, the thickness range of the semiconductor layer 130′ may be from about 200 Å to about 500 Å, but the present invention is not limited thereto.

Subsequently, as shown in FIG. 2, patterning process is performed on the light absorption layer 120′ and the semiconductor layer 130′, and a part of the semiconductor layer 130′ and a part of the light absorption layer 120′ are removed to respectively form a patterned light absorption layer 120 and a patterned semiconductor layer 130. Specifically, in this embodiment, a photoresist layer can be disposed on the semiconductor layer 130′, and a patterned photoresist layer PR is defined by means of a photolithography process, so as to shield a part of the semiconductor layer 130′ (shown in FIG. 1) and a part of the light absorption layer 120′ (shown in FIG. 1), and then, an etching process is performed on the semiconductor layer 130′ and the light absorption layer 120′ by using the patterned photoresist layer PR as an etch resist, and a part of the semiconductor layer 130′ and a part of the light absorption layer 120′ that are not shielded by the patterned photoresist layer PR are removed, so as to respectively form the patterned light absorption layer 120 and the patterned semiconductor layer 130. In this embodiment, a pattern range of the patterned light absorption layer 120 is approximately equal to a pattern range of the patterned semiconductor layer 130, but the present invention is not limited thereto.

Subsequently, as shown in FIG. 3, the patterned photoresist layer PR is removed, then, a patterned gate insulating layer GI and a gate G are formed on the patterned semiconductor layer 130, the patterned gate insulating layer GI and the gate G are stacked in sequence on the patterned semiconductor layer 130, and the patterned semiconductor layer 130 is defined by an area shielded by the gate G as a semiconductor channel 130C, where the gate G is a conductive electrode, a material thereof includes metal, an alloy, and a transparent conductive material (for example, indium zinc (IZO), indium tin oxide (ITO), zinc oxide (ZnO), or another suitable material), an organic conductive material (for example, a polymer-mixed conductive particle, polythiophene, polyactetylene, pentacene, or another suitable material), or another suitable material, or a combination of the foregoing. Manners for manufacturing the patterned gate insulating layer GI and the gate G may be similar to the foregoing methods for manufacturing the patterned light absorption layer 12 and the patterned semiconductor layer 130, or another suitable patterning process is utilized, which is not described again herein. In this embodiment, the patterned gate insulating layer GI being located inside a range of perpendicular projection of the patterned semiconductor layer 130 onto the transparent substrate 110 is used as a preferred example, but the present invention is not limited thereto. Subsequently, as shown in FIG. 4, a dielectric layer 140 is formed on the transparent substrate 110 and covers the patterned semiconductor layer 130 and the gate G, an etching process is further performed to from a plurality of dielectric layer holes 140H in the a dielectric layer 140, and each dielectric layer hole 140H exposes a part of the patterned semiconductor layer 130, that is, each dielectric layer hole 140H partially overlaps with the patterned semiconductor layer 130. A material of the dielectric layer 140 may include silicon nitride or silicon oxide, an organic material, or another suitable material, but the present invention is not limited thereto. According to this embodiment, the dielectric layer 140 may be silicon nitride having a high hydrogen content, and a material of the patterned semiconductor layer 130 may be metal oxide. Therefore, when the dielectric layer 140 is in contact with the patterned semiconductor layer 130, hydrogen in the dielectric layer 140 reduces metal oxide in the patterned semiconductor layer 130, so that a part, which is in contact with dielectric layer 140, in the patterned semiconductor layer 130 may have conductivity close to conductivity of a conductor, and inner resistance in the patterned semiconductor layer 130 is further reduced.

Finally, as shown in FIG. 5, a source S and a drain D are formed on the patterned semiconductor layer 130, accurately, the source S and the drain D are disposed on the dielectric layer 140, and are electrically connected to the patterned semiconductor layer 130 respectively through the dielectric layer holes 140H, so as to form the thin film transistor 100 of this embodiment. The source S and drain D are both conductive electrodes and are spaced from each other, and materials thereof include metal, an alloy, a transparent conductive material (for example, indium zinc oxide (IZO), indium tin oxide (ITO), zinc oxide (ZnO), or another suitable material), an organic conductive material (for example, a polymer-mixed conductive particle, polythiophene, polyactetylene, pentacene, or another suitable material), or another suitable material, or a combination of the foregoing. It should be noted that the thin film transistor 100 formed in this embodiment is a self-aligned top gate thin film transistor, so that overlapped area among the gate G, source S, and drain D in the thin film transistor 100 may be reduced, so as to reduce parasitic capacitance, and meanwhile, an area size occupied by the thin film transistor 100 can be reduced to further achieve miniaturization of the thin film transistor 100, for example, a length of the semiconductor channel 130C in the thin film transistor 100 may be less than 5 μm and greater than 0 μm, but the present invention is not limited thereto. In other words, in this embodiment, all of the gate G, source S, and drain D being located inside a range of perpendicular projection of the patterned semiconductor layer 130 onto the transparent substrate 110 is used as a preferred example, but the present invention is not limited thereto.

Referring to FIG. 5 again, a structure of the thin film transistor 100 manufactured by means of the foregoing method for manufacturing the thin film transistor 100 of a display panel of the first embodiment of the present invention is described as below. The thin film transistor 100 of this embodiment includes a patterned light absorption layer 120, a patterned semiconductor layer 130, a patterned gate insulating layer GI, a gate G, a dielectric layer 140, a source S, and a drain D. The patterned light absorption layer 120 is disposed on the transparent substrate 110, the patterned semiconductor layer 130 is disposed on the patterned light absorption layer 120, the patterned gate insulating layer GI is disposed on the patterned semiconductor layer 130, and the gate G is disposed on the patterned gate insulating layer GI. In this embodiment, the patterned gate insulating layer GI being located inside a range of perpendicular projection of the patterned semiconductor layer 130 onto the transparent substrate 110 is used as a preferred example, but the present invention is not limited thereto. The dielectric layer 140 is disposed on the gate G and covers the gate G and the patterned semiconductor layer 130 at the same time, and the dielectric layer 140 includes a plurality of dielectric layer holes 140H and exposes a part of the patterned semiconductor layer 130, that is, each dielectric layer hole 140H partially overlaps with the patterned semiconductor layer 130. The source S and the drain D are disposed on the patterned semiconductor layer 130 are electrically connected to the patterned semiconductor layer 130 respectively, where the source S and the drain D are disposed on a surface of the dielectric layer 140 and are electrically connected to the patterned semiconductor layer 130 respectively through different dielectric layer holes 140H, so as to construct a self-aligned top gate thin film transistor. In other words, in this embodiment, all of the gate G, source S, and drain D being located inside a range of the patterned semiconductor layer 130 that is perpendicularly projected onto the transparent substrate 110 is used as a preferred example, but the present invention is not limited thereto. In addition, a display panel of this embodiment may be active display panel, such as an active matrix organic light emitting diode (AMOLED) display panel, or a non-active display panel, such as a liquid crystal display panel, but the present invention is not limited thereto. Further, the display panel of this embodiment may be a flat display panel, a curved-display panel, a flexible display panel, or another suitable display panel.

It should be noted that because amorphous silicon has a property of absorbing a short-wavelength light ray (for example, ultraviolet light, blue light, and green light), when a material of the patterned light absorption layer 120 of the thin film transistor 100 of this embodiment is amorphous silicon, the patterned light absorption layer 120 may absorb a short-wavelength light ray from a transparent substrate 110 side and effectively reduce an amount of illumination of the short-wavelength light ray from the transparent substrate 110 side onto the patterned semiconductor layer 130, so as to further protect the semiconductor channel 130C and reduce a threshold voltage offset, thereby maintaining a switch effect of the thin film transistor 100. In addition, because the thin film transistor 100 of this embodiment is a top gate thin film transistor, and the gate G is a metal electrode, the semiconductor channel 130C in the patterned semiconductor layer 130 can be shielded by the gate G from being illuminated by a short-wavelength light ray from another side, that is, the semiconductor channel 130C in the patterned semiconductor layer 130 can reduce an amount of illumination of the short-wavelength light ray by means of protection of the patterned light absorption layer 120 and the gate G.

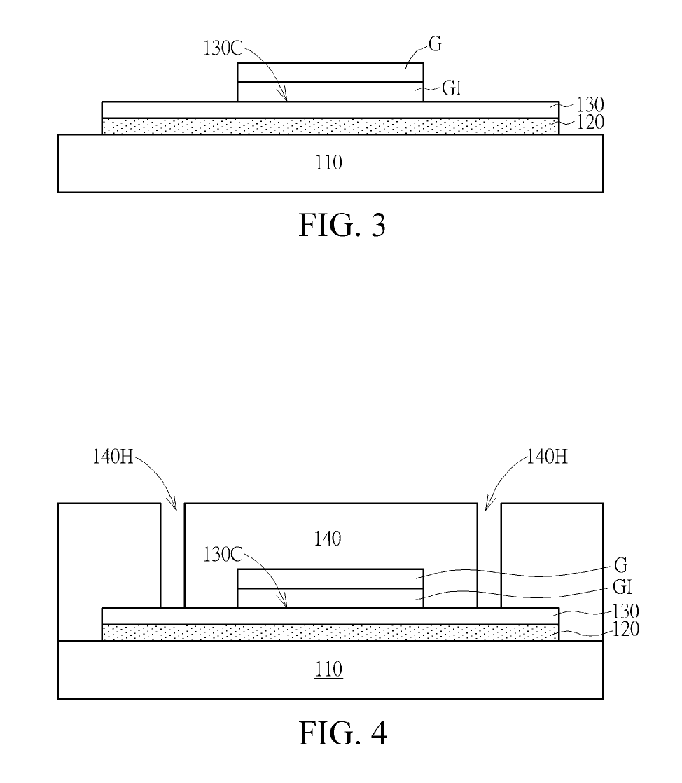

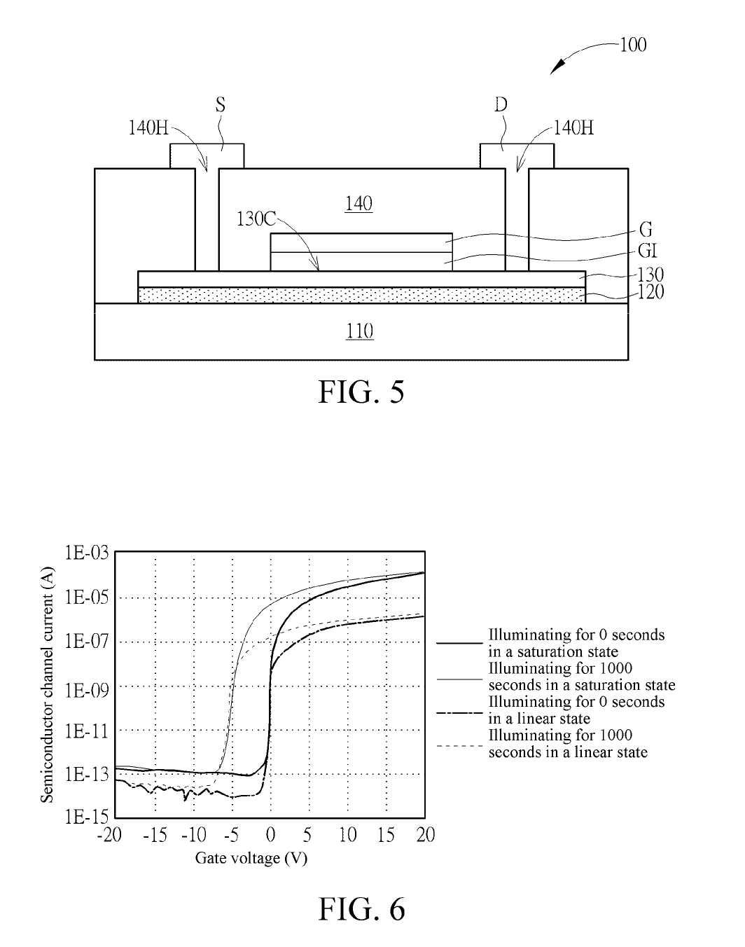

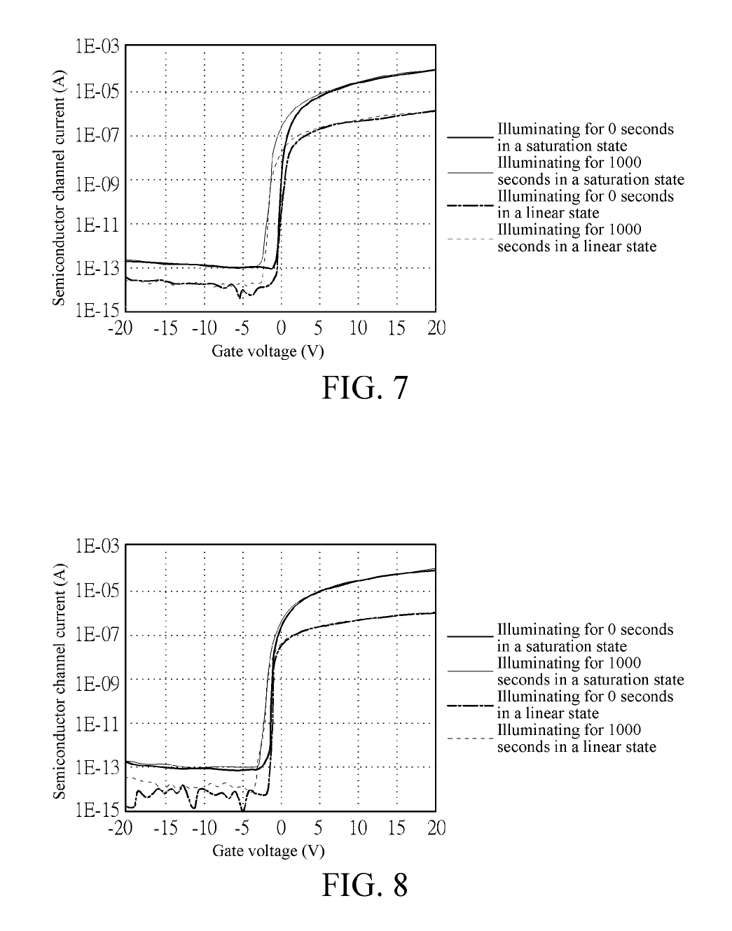

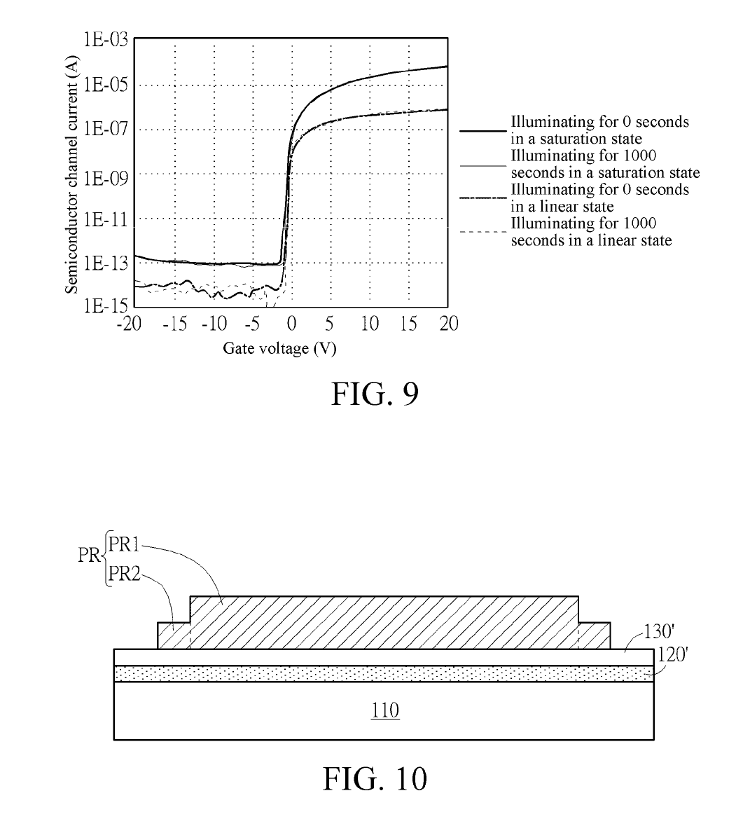

Referring to FIG. 6 to FIG. 9, FIG. 6 shows an experimental result of a negative bias illumination stress (NBIS) test on a thin film transistor of a display panel of a comparison embodiment of the present invention, FIG. 7 shows an experimental result of a positive bias illumination stress (PBIS) test on a thin film transistor of a display panel of a comparison embodiment of the present invention, FIG. 8 shows an experimental result of an NBIS test on the thin film transistor of a display panel of the first embodiment of the present invention, and FIG. 9 shows an experimental result of a PBIS test on the thin film transistor of a display panel of the first embodiment of the present invention, where the comparison embodiment of the present invention is a top gate thin film transistor where no patterned light absorption layer 120 is disposed below a patterned semiconductor layer 130, and a light source illuminates below the transparent substrate 110. In addition, in the NBIS test, the brightness of the illuminating light source is about 5000 nits, a gate voltage of a tested thin film transistor is fixedly about −30 volts (V) from 0 seconds to 1000 seconds, a source and a drain are fixedly 0 V, meanwhile, electrical properties of a component before and after the NBIS test are measured, a gate measurement range is from about −20 V to about +20 V, a source voltage is about 0 V, and a drain voltage is about 0.1 V or about 10 V, so as to respectively test semiconductor channel currents in a linear state and in a saturation state, while in the PBIS test, the brightness of the illuminating light source is about 5000 nits, a gate voltage of the tested thin film transistor is fixedly about 30 V from about 0 seconds to about 1000 seconds, a source and a drain are fixedly 0 V, meanwhile, electrical properties of a component before and after the PBIS test are measured, a gate measurement range is from about −20 V to about +20 V, a source voltage is about 0 V, and a drain voltage is about 0.1 V or about 10 V, so as to respectively test semiconductor channel currents in a linear state and in a saturation state. As shown in FIG. 7 and FIG. 8, a threshold voltage of the thin film transistor of a display panel of the comparison embodiment of the present invention, no mater during an NBIS test or a PBIS test, is always about 0 V under a condition where there is no illumination, but in FIG. 9, when an illumination time of the NBIS test reaches up to about 1000 seconds, the threshold voltage of the thin film transistor of the comparison embodiment deviates by −5.06 V, and in FIG. 7, when an illumination time of the PBIS test reaches up to about 1000 seconds, the threshold voltage of the thin film transistor of the comparison embodiment deviates by −1.33 V, that is, after the thin film transistor of the comparison embodiment is illuminated, the threshold voltage thereof starts to deviate, and when the illumination time reaches up to about 1000 seconds, the threshold voltage deviates severely, thereby further affecting operation of the thin film transistor. Upon comparison, as shown in FIG. 8 and FIG. 9, when an illumination time of the thin film transistor 100 of a display panel of the first embodiment of the present invention reaches up to 1000 seconds, in an NBIS test, a threshold voltage of the thin film transistor 100 of this embodiment merely deviates by −0.72 V, and in a PBIS test, a threshold voltage of the thin film transistor 100 of this embodiment merely deviates by 0.07 V. Therefore, the foregoing experiment, it could be proved that disposition of the patterned light absorption layer 120 can protect the patterned semiconductor layer 130 of the thin film transistor 100, greatly reduce an offset threshold voltage, and maintain a switch effect of the thin film transistor 100.

The method for manufacturing the thin film transistor of a display panel of the present invention is not limited to the foregoing embodiments. A thin film transistor of a display panel and a method for manufacturing the same of other preferred embodiments of the present invention are described in sequence below, and in order to facilitate comparison of differences between respective embodiments and simplify descriptions, the same reference signs are used to mark the same components in the respective embodiments below, descriptions are made mainly on differences between the embodiments, and repeated parts are not described again.

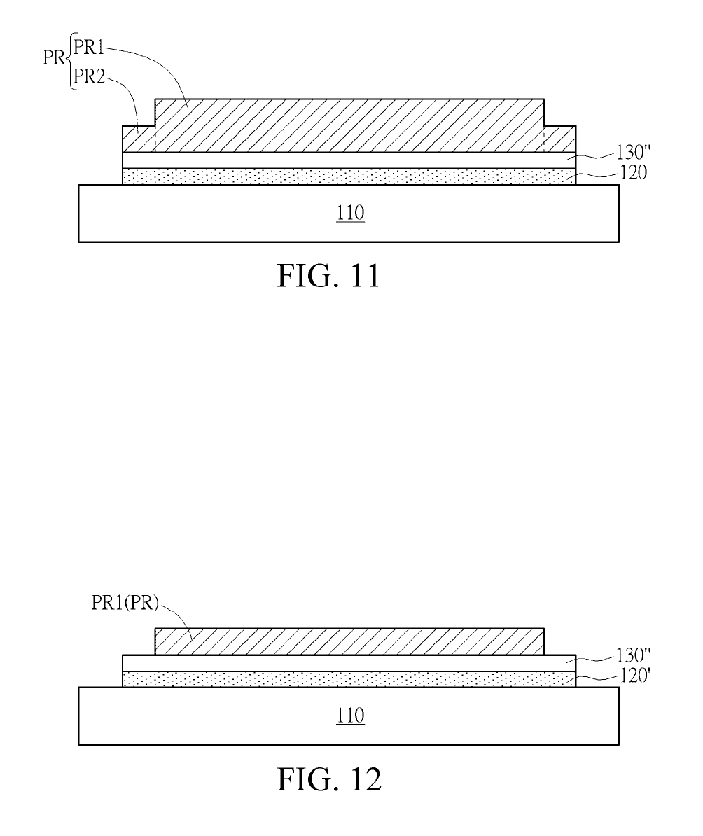

Referring to FIG. 10 to FIG. 14, FIG. 10 to FIG. 14 show schematic diagrams of a method for manufacturing a thin film transistor of a display panel of a second embodiment of the present invention, and FIG. 14 shows a schematic sectional diagram of the thin film transistor of a display panel of the second embodiment of the present invention at the same time. As shown in FIG. 10 and FIG. 14, a method for manufacturing a thin film transistor 200 of a display panel of this embodiment differs from that of the first embodiment in processing manners of a patterned light absorption layer 120 and a patterned semiconductor layer 130. In FIG. 14, after a photoresist layer is disposed on a semiconductor layer 130′, photolithography is performed by using a gray-scale mask or a half tone mask, so as to form a patterned photoresist layer PR on the semiconductor layer 130′, where the patterned photoresist layer PR includes a first part PR1 and a second part PR2, the second part PR2 is disposed on two sides of the first part PR1, and the thickness of the first part PR1 is greater than the thickness of the second part PR2, that is, the patterned photoresist layer PR of this embodiment has two different thicknesses. Subsequently, as shown in FIG. 11, a part of the semiconductor layer 130′ and a part of the light absorption layer 120′ that are not shielded by the patterned photoresist layer PR are removed to respectively form the patterned light absorption layer 120 and a semi-patterned semiconductor layer 130″. Subsequently, as shown in FIG. 12, the second part PR2 of the patterned photoresist layer PR is removed. In this embodiment, dry etching, plasma etching, reactive ion etching (RIE) or another suitable etching technique may be used to remove the patterned photoresist layer PR. Because the patterned photoresist layer PR has two different thicknesses, and the thickness of the first part PR1 is greater than the thickness of the second part PR2, the second part PR2 of the patterned photoresist layer PR is first removed in the etching process as compared with the first part PR1, that is, in the process of etching the patterned photoresist layer PR, a part of the first part PR1 and a part of the second part PR2 are removed at the same time, while the thickness of the first part PR1 and the thickness of the second part PR2 decrease with the etching process, and the etching is stopped in a situation where the second part PR2 is removed and a part of the first part PR1 remains, so that a part of the semi-patterned semiconductor layer 130″ is not shielded by the first part PR1 of the patterned photoresist layer PR. Subsequently, as shown in FIG. 13, the part of the semi-patterned semiconductor layer 130″ that is not shielded by the first part PR1 of the patterned photoresist layer PR is removed to form the patterned semiconductor layer 130, and then, the remaining patterned photoresist layer PR is removed. Finally, as shown in FIG. 14, a patterned gate insulating layer GI, a gate G, a dielectric layer 140, a source S, and a drain D are manufactured in a processing manner the same as that of the first embodiment, so as to form a thin film transistor 200 of this embodiment.

Referring to FIG. 14 again, a structure of the thin film transistor 200 of this embodiment differs from that of the first embodiment in that a pattern range (or an area, namely, an area of perpendicular projection onto the transparent substrate 110) of the patterned light absorption layer 120 is greater than a pattern range (or an area, namely, an area of perpendicular projection onto the transparent substrate 110) of the patterned semiconductor layer 130. Because the pattern range of the patterned light absorption layer 120 is greater than the pattern range of the patterned semiconductor layer 130, an amount of an illumination of a short-wavelength light ray from a transparent substrate 110 side onto the patterned semiconductor layer 130 by means of lateral illumination may be further reduced, so that the patterned light absorption layer 120 of this embodiment may provide preferable light ray protection for the patterned semiconductor layer 130 of the thin film transistor 200.

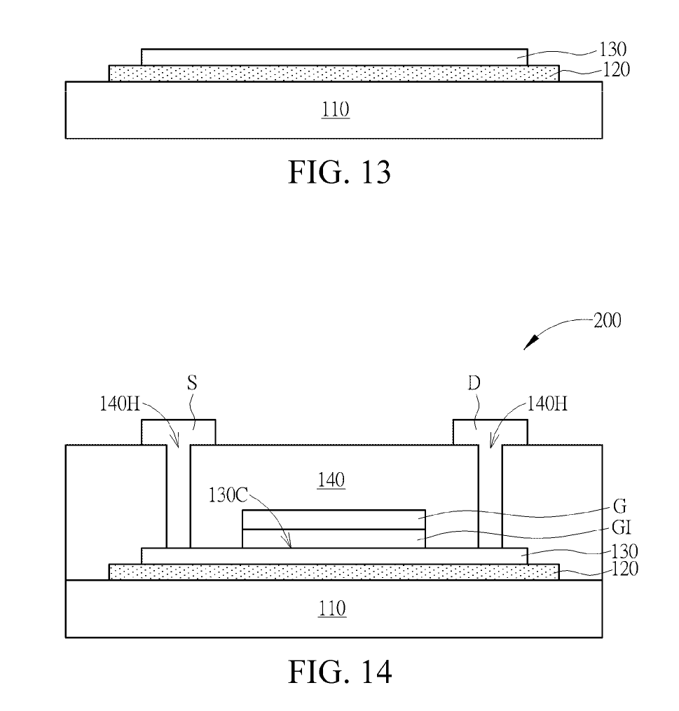

Referring to FIG. 15, FIG. 15 shows a schematic sectional diagram of a thin film transistor of a display panel of a third embodiment of the present invention. As shown in FIG. 15, a thin film transistor 300 of this embodiment differs from that of the first embodiment in that the thin film transistor 300 of this embodiment further includes a barrier layer 310, where the barrier layer 310 is disposed between the patterned light absorption layer 120 and the patterned semiconductor layer 130. Because the material of the patterned light absorption layer 120 may be amorphous silicon having a high hydrogen content, and the material of the patterned semiconductor layer 130 may be metal oxide, an organic semiconductor, an amorphous silicon semiconductor, or the like, when the barrier layer 310 is disposed between the patterned light absorption layer 120 and the patterned semiconductor layer 130, hydrogen in the patterned light absorption layer 120 can prevented from reducing metal oxide in the patterned semiconductor layer 130 when the patterned light absorption layer 120 is in contact with patterned semiconductor layer 130, thereby preventing a semiconductor channel 130C of the patterned semiconductor layer 130 form possessing a conductive property close to that of a conductor to affect operation of the thin film transistor 300. In addition, in this embodiment, a material of the barrier layer 310 may include silicon oxide, aluminum oxide, or other suitable insulating metal oxide. Moreover, in other embodiments, if the amorphous silicon semiconductor material is selected to manufacture the patterned semiconductor layer 130, because the patterned light absorption layer 120 can absorb most light, the patterned semiconductor layer 130 can be further protected. The barrier layer 310 of this embodiment may also be used in the thin film transistor of a display panel of the present invention.

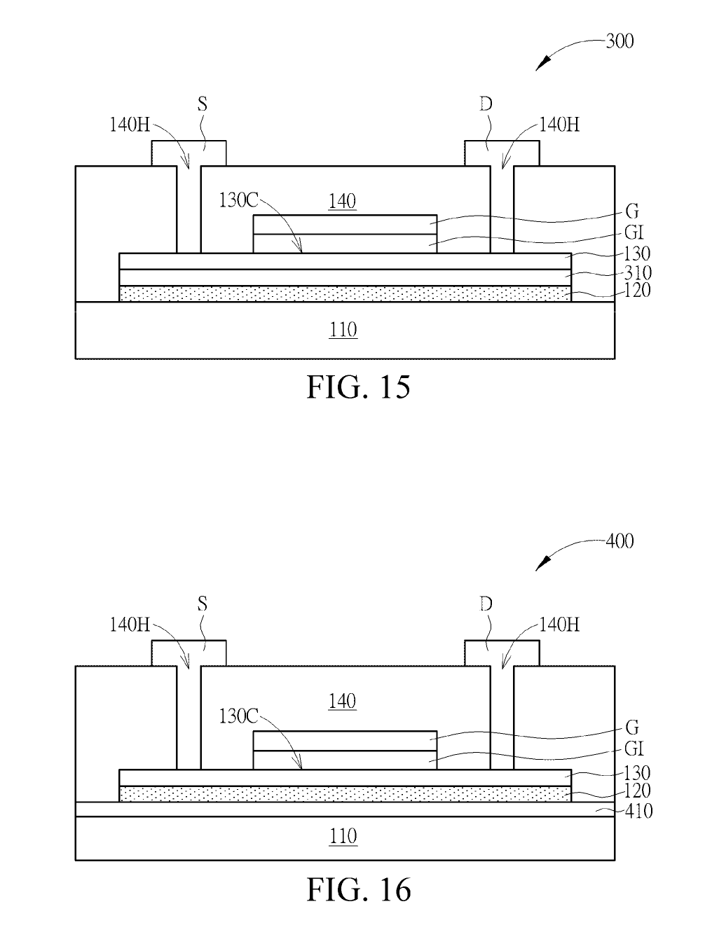

Referring to FIG. 16, FIG. 16 shows a schematic sectional diagram of a thin film transistor of a display panel of a fourth embodiment of the present invention. As shown in FIG. 16, a thin film transistor 400 of this embodiment differs from that of the first embodiment in that the thin film transistor 400 of this embodiment further includes a barrier layer 410, where the barrier layer 410 is disposed between the transparent substrate 110 and the patterned light absorption layer 120. Because the buffer layer 410 is disposed between the transparent substrate 110 and the patterned light absorption layer 120, the buffer layer 410 may protect the transparent substrate 110 from being damaged by a chemical solution such as a developer or a photoresist remover in a processing procedure, so as to maintain a yield rate and quality of a display panel, in particular, a flexible display panel formed by using a flexible transparent substrate. In this embodiment, a material of the buffer layer 410 may include silicon nitride, silicon oxide or another material suitable for manufacturing the buffer layer 410, a material of the transparent substrate 110 may include polyimide or another material suitable for manufacturing a flexible transparent substrate. The barrier layer 410 of this embodiment may also be used in the thin film transistor of a display panel of the second embodiment and the third embodiment of the present invention.

In conclusion, a top gate thin film transistor is used a preferred example of the thin film transistor of a display panel of the present invention, and as compared with a bottom gate thin film transistor and a dual gate thin film transistor, the thin film transistor of the present invention may have a smaller size and may also avoid a parasitic capacitance problem. Further, because the thin film transistor of a display panel of the present invention includes a patterned light absorption layer disposed between a transparent substrate and a patterned semiconductor layer, and the patterned light absorption layer can absorb a short-wavelength light ray from a transparent substrate side, an amount of illumination of the short-wavelength light ray from the transparent substrate side onto the patterned semiconductor layer can be reduced, so as to effectively reduce a threshold voltage offset, thereby maintaining a switch effect of the thin film transistor.

The foregoing are merely preferred embodiments of the present invention, and equivalent alternation and modification made according to the claims of the present invention are covered by the present invention.

What is claimed is:

1. A thin film transistor of a display panel, comprising:
a transparent substrate;
a patterned light absorption layer, disposed on the transparent substrate;
a patterned semiconductor layer, disposed on the patterned light absorption layer;
a patterned gate insulating layer, disposed on the patterned semiconductor layer;
a gate, disposed on the patterned gate insulating layer;
a source, disposed on the patterned semiconductor layer and electrically connected to the patterned semiconductor layer; and
a drain, disposed on the patterned semiconductor layer and electrically connected to the patterned semiconductor layer.

2. The thin film transistor of the display panel according to claim 1, wherein a light absorption pattern range of the patterned light absorption layer is greater than or equal to a semiconductor pattern range of the patterned semiconductor layer.

3. The thin film transistor of the display panel according to claim 1, wherein the patterned light absorption layer is an amorphous silicon layer.

4. The thin film transistor of the display panel according to claim 1, further comprising a barrier layer, disposed between the patterned light absorption layer and the patterned semiconductor layer.

5. The thin film transistor of the display panel according to claim 4, wherein a material of the barrier layer comprises one of silicon oxide and metal oxide.

6. The thin film transistor of the display panel according to claim 1, further comprising a dielectric layer, disposed on the gate.

7. The thin film transistor of the display panel according to claim 6, wherein the dielectric layer having a dielectric layer hole, the source and the drain are disposed on the dielectric layer, and the source and the drain are electrically connected to the patterned semiconductor layer separately through the dielectric layer hole.

8. The thin film transistor of the display panel according to claim 6, wherein a material of the dielectric layer comprises silicon nitride.

9. The thin film transistor of the display panel according to claim 1, wherein the transparent substrate is a flexible substrate.

10. The thin film transistor of the display panel according to claim 9, further comprising a barrier layer, disposed between the transparent substrate and the patterned light absorption layer.

11. The thin film transistor of the display panel according to claim 10, further comprises a buffer layer, wherein the transparent substrate comprises polyimide, and the buffer layer comprises silicon nitride or silicon oxide.

12. The thin film transistor of the display panel according to claim 1, wherein the patterned semiconductor layer comprises a metal oxide semiconductor material, an amorphous silicon semiconductor, or organic semiconductor material.

13. A method for manufacturing a thin film transistor of a display panel, comprising:
providing a transparent substrate;
forming an initial light absorption layer and an initial semiconductor layer in sequence on the transparent substrate;
forming a patterned light absorption layer by creating a first pattern with a light absorption pattern range on the initial light absorption layer, forming a patterned semiconductor layer by creating a second pattern with a semiconductor pattern range on the initial semiconductor layer, wherein the light absorption pattern range is greater than or equal to the semiconductor pattern range;
forming a patterned gate insulating layer and a gate on the patterned semiconductor layer, wherein the patterned gate insulating layer and the gate are stacked in sequence on the patterned semiconductor layer; and
forming a source and a drain on the patterned semiconductor layer, wherein the source and the drain are electrically connected to the patterned semiconductor layer separately.

14. The method for manufacturing the thin film transistor of the display panel according to claim 13, further comprising, before forming the pattern semiconductor layer and the patterned light absorption layer, forming a patterned photoresist layer on the initial semiconductor layer by performing a photolithography process by using a gray-scale mask or a half tone mask, wherein the patterned photoresist layer comprises a first part and a second part, the second part is disposed on two sides of the first part, and the first part is thicker than the second part.

15. The method for manufacturing the thin film transistor of the display panel according to claim 14, further comprising:
creating the semiconductor pattern and the light absorption pattern on where not shielded by the patterned photoresist layer;
removing the second part of the patterned photoresist layer; and
creating the semiconductor pattern on where not shielded by the first part of the patterned photoresist layer.

16. The method for manufacturing the thin film transistor of the display panel according to claim 14, wherein the light absorption pattern range is greater than the semiconductor pattern range.

17. The method for manufacturing the thin film transistor of the display panel according to claim 13, wherein the patterned light absorption layer is an amorphous silicon layer.

18. The method for manufacturing the thin film transistor of the display panel according to claim 13, comprising forming a barrier layer, disposed between the patterned light absorption layer and the patterned semiconductor layer.

19. The method for manufacturing the thin film transistor of the display panel according to claim 18, wherein the barrier layer comprises one of silicon oxide and metal oxide.

20. The method for manufacturing the thin film transistor of the display panel according to claim 13, further comprising forming a dielectric layer on the transparent substrate, wherein the dielectric layer covers the gate and the patterned semiconductor layer.

21. The method for manufacturing the thin film transistor of the display panel according to claim 20, wherein the source and the drain are formed on the dielectric layer, and the source and the drain are electrically connected to the patterned semiconductor layer separately through a dielectric layer hole of the dielectric layer.

22. The method for manufacturing the thin film transistor of the display panel according to claim 20, wherein the dielectric layer comprises silicon nitride.

23. The method for manufacturing the thin film transistor of the display panel according to claim 13, wherein the transparent substrate is a flexible substrate.

24. The method for manufacturing the thin film transistor of the display panel according to claim 23, further comprising, forming a buffer layer on the transparent substrate before forming the initial light absorption layer.

25. The method for manufacturing the thin film transistor of the display panel according to claim 24, wherein the transparent substrate comprises polyimide, and the buffer layer comprises silicon nitride or silicon oxide.

26. The method for manufacturing the thin film transistor of the display panel according to claim 13, wherein the patterned semiconductor layer comprises a metal oxide semiconductor material, an amorphous silicon semiconductor, or organic semiconductor material.
